(19) United States
(12) Patent Application Publication
(10) Pub. No.: US 2025/0242695 A1
(43) Pub. Date: Jul. 31, 2025

(54) SYSTEMS AND METHODS FOR FOLDED DISPLAYS AND VIRTUAL DISPLAY SYSTEMS IN A VEHICLE

(71) Applicant: BRELYON INC., San Mateo, CA (US)

(72) Inventors: Barmak Heshmat DEHKORDI, San Mateo, CA (US); Christopher BARSI, Lee, NH (US)

(73) Assignee: BRELYON INC., San Mateo, CA (US)

(21) Appl. No.: 19/035,313

(22) Filed: Jan. 23, 2025

Related U.S. Application Data
(60) Provisional application No. 63/624,969, filed on Jan. 25, 2024.

(51) Int. Cl. B60K 35/22; G02B 27/28; G02B 30/40

(52) U.S. Cl. CPC B60K 35/223; G02B 27/283; G02B 30/40; B60K 2360/166

(57) ABSTRACT

A display system and method for generating virtual images or light field images includes, in some embodiments, a display and a field-evolving cavity. The field-evolving cavity modulates the optical depth of the virtual image. In some embodiments, the display is a folded display. In some embodiments, the display system is integrated into a part of a vehicle and serves as an instrument cluster, navigation display, or entertainment center. Other components of the display system may be bent.

### FIELD OF THE INVENTION

The present invention relates generally to light-field displays. More specifically, the present invention is a system for creating compact light-field displays using a single display panel that is folded and segmented to produce multiple images.

### BACKGROUND

Virtual display systems are designed and implemented with various specifications. For example, in U.S. Pat. No. 11,067,825 B2 and U.S. Pat. No. 10,768,442 B1, Dehkordi described a virtual display system providing monocular and binocular depth cues to achieve realistic depth perception effects. In U.S. Pat. No. 11,592,684 B2, Dehkordi disclosed an optical component called a field-evolving cavity, which folds light back and forth for multiple round trips with the cavity, to make the light source appear farther from the viewer compared to the distance to the physical display system. In U.S. Pat. No. 11,196,976 B2, Dehkordi further disclosed a virtual display system directed to tessellating a light field into a size or depth that is extended beyond the pupil size of a display system. In U.S. Pat. No. 11,662,591 B1, Dehkordi et al disclosed an apparatus for modifying the monocular depth of virtual images dynamically and for producing a multifocal virtual image using flat display panels. In U.S. Pat. No. 11,320,668 B2, Dehkordi et al disclosed a method of modifying the optical quality or the properties of a display system using optical fusion, which combines computational methods with optical architectures to remove visual artifacts from the images produced by the display system.

### SUMMARY

In present society, there has been an increasing traction towards more immersive light-field and/or autostereoscopic three-dimensional (3D) displays due to advancements in electronics and micro fabrications. Unlike stereoscopic 3D, light-field displays manipulate the wavefront to create depth perception at the monocular level. This can eliminate the accommodation-vergence mismatch and reduce stress on the user's eyes. There have been breakthroughs for realizing more realistic light-field experiences, which can be described in four major methods for creating such experiences, each method each having its own weaknesses and advantages: super multi-view, computational, multi-focal, and holographic. The super multi-view method provides a light-field at a very compact form but is limited to a very small viewing zone and low resolution. The computational method increases the resolution but produces haze and temporal flickering artifacts. The holographic method can struggle with color nonuniformity and fringing or specular artifacts. The multi-focal method can produce clean, but not scalable, images. Also, devices employing a multi-focal method can be bulky. However, universal to all current methods of light field displays are these following issues: large bandwidth requirements; a reliance on expensive and/or advanced components that are not easily mass produced such as tunable lenses; poor color uniformity, small field of view or viewing zone, low brightness, haze and diffraction artifacts, limited depth range; and the occasional necessity to wear specialized glasses. These challenges have significantly limited the use or production of light-field displays in commercial and/or industrial settings. Therefore, what is needed is a thorough class of optical methods that in some embodiments uses a set of reflectors positioned in a cavity to multiplex different liquid crystal displays (LCDs) or different portions of a single LCD onto different optical focal planes. This can allow a light-field within the cavity to adapt into or to certain optical depth(s) before it exits the cavity's exit pupil, while resolving the previously discussed issues associated with other methods of light-field display.

An objective of the present invention is to provide users with a device that can be a compact system of creating light-field displays at or through varying optical depths. The present invention intends to provide users with a device that addresses the previously discussed issues associated with current methods of light field displays. The present invention intends to provide users with a device that is less expensive and easier to produce at or for commercial and/or industrial levels. The present invention intends to provide users with a device that reduces artifacts without reducing the clarity of the light-field display. The present invention intends to provide users with a device that allows users to produce content for light-field displays more easily than conventional stereoscopic displays. The present invention intends to provide users with a device that does not require additional accessories or specialized components to be utilized by the user in order to view the content of the light-field display, such as specialized glasses or rending engines, respectively. The present invention intends to provide users with a device that can reduce an optical path difference to each focal plane of the light-field display and minimize the light loss from polarization. The present invention intends to provide users with a device that can vary the display focal plane without any mechanical motion.

The present invention is a system for creating compact light-field displays through varying optical depths. The present invention primarily contains a housing. The housing contains a plurality of panels in a variety of arrangements in which the present invention can produce light-field displays of varying degrees or scope. The present invention also contains a relay panel. The present invention contains a cover case atop the housing.

Realizing accurate light-field displays usually requires advanced optical structures that use high-cost light sources and spatial modulators such as laser scanners, tunable lenses; liquid crystal on silicon (LCoS) reflectors or digital micro-mirror devices (DMDs). Accordingly, these existing methods do not provide true optical depth which means that there is inaccuracy in the wavefront in the form of diffraction color inaccuracy, speckle, or haze. A class of displays systems and methods revolves around the concept of field-evolving (FE) cavities. These cavities prepare the light in such a way that it provides true optical depth with no distortion to the wavefront, and, therefore, the images provided by such systems are as accurate as a normal display panel. This method uses conventional LCD or organic light-emitting diode (OLED) panel displays in a fashion that provides multiple optical focal planes simultaneously or sequentially in opaque or augmented (transparent) modality. The system can also be conveniently packaged in a small form factor well suited to desktop uses. Since the cavity feeds regular two-dimensional (2D) images and combines them optically into a 3D light-field, there is no need for complex rendering engines. The methods are also scalable to large-scale displays for commercial uses.

In some embodiments, a system comprises a folded display having a plurality of flat portions continuously connected by at least one bent portion, each flat portion emitting light, a plurality of first polarization-changing semi-reflectors disposed to receive the light emitted from each of the flat portions, a second polarization-changing semi-reflector to reflect a portion of light and an aperture optic to direct the light out of the system, wherein the light is guided along a plurality of optical paths within the system by the plurality of first polarization-changing semi-reflectors, the second polarization-changing semi-reflector, and the aperture optic, and the light forms a virtual image with respect to a headbox outside the system.

In some embodiments, the virtual image is a multifocal image.

In some embodiments, the virtual image has a monocular depth that is larger than a distance between the display panel and the headbox.

In some embodiments, the aperture optic comprises a reflective polarizer, an absorptive polarizer, and an antireflection layer.

In some embodiments, the light is transmitted through each of the reflective polarizer, the absorptive polarizer, and the antireflection layer prior to exiting the system.

In some embodiments, the plurality of first polarization changing semi-reflectors and the second polarization-changing semi-reflector each comprise a wave plate and a beam splitter.

In some embodiments each of the wave plates is a quarter-wave plate.

In some embodiments, a vehicle has the system integrated as an instrument cluster of the vehicle.

In some embodiments, the system further comprises a camera to capture information about an external environment and to display the information on the folded display.

In some embodiments, the system further comprises a camera to capture information about a viewer and to display the information on the folded display.

In some embodiments, a shape of the folded display is selected from the group consisting of a C-shape, a U-shape, an L-shape, a sawtooth-shape, and combinations thereof.

In some embodiments, at least one of the polarization-changing semi-reflectors further comprises an electro-optic (EO) material.

In some embodiments, at least one of the plurality of optical paths is partially folded onto itself.

In some embodiments, a lateral size of the virtual image is larger than a lateral size of the aperture optic.

In some embodiments, at least two of the plurality of first polarization-changing semi-reflectors correspond to a respective flat portion a folded semi-reflector, the respective flat portions connected by a bent portion.

In some embodiments, the folded display further comprises an extended portion that directs light out of the system without incidence on the plurality of first polarization-changing semi-reflectors and without incidence on the second polarization-changing semi-reflector, and the extended portion is touch sensitive.

In some embodiments, the virtual image is a first virtual image, and the light is further emitted from the at least one bent portion of the folded display and travels along at least one of the plurality of optical paths to form a second virtual image.

In some embodiments, a system comprises a folded display panel having a plurality of substantially flat portions, each such portion emitting a respective plurality of light rays; and a field-evolving cavity having a plurality of specular reflectors to receive the plurality of light rays and to guide the light rays along a respective plurality of optical paths within the field-evolving cavity; and an aperture optic to transmit the light out of the system, wherein the plurality of light rays forms a virtual image.

In some embodiments, at least a portion of the optical path is folded onto itself.

In some embodiments, the virtual image is a multifocal virtual image.

In some embodiments, the field evolving cavity further comprises an electro-optic (EO) plate disposed along at least one of the optical paths.

In some embodiments, each of the plurality of specular reflectors comprises a wave plate and a beam splitter.

In some embodiments, the wave plate is a quarter-wave plate.

In some embodiments, adjacent substantially flat portions of the plurality of substantially flat portions of the folded display are oriented at a right angle relative each other.

In some embodiments, a vehicle has the system integrated into the vehicle as an instrument cluster or navigation system.

In some embodiments, the folded display is a folded OLED display.

In some embodiments, the system further comprises a camera to capture information about an external environment to display the information on the folded display.

In some embodiments, a a system comprises a folded display having a plurality of flat portions continuously connected by bent portions, each flat portion emitting light; a field-evolving cavity to direct a first portion of the light from the display panel and to produce a virtual image, the field-evolving cavity having a plurality of polarization-dependent specular reflectors; and an aperture optic, wherein one of the plurality of flat portions of the folded display is touch sensitive and further emits a second portion of light that traverses away from the field-evolving cavity.

In some embodiments, each of the polarization-dependent specular reflectors comprises a quarter-wave plate and a beam splitter.

In some embodiments, the aperture optic comprises a reflective polarizer, and absorptive polarizer, and an antireflection layer.

In some embodiments, a vehicle has the system integrated into the vehicle.

### BRIEF DESCRIPTION OF THE DRAWINGS

FIG. 1 illustrates a set of common optical components used in the disclosed invention.

FIGS. 2A through 2D depict a set of architectures and subassemblies of the components of FIG. 1, some of the architectures forming field-evolving cavities.

FIGS. 3A through 3V show various embodiments of the disclosed invention that use folded display panels to produce display content.

FIGS. 4A through 4D depict various methods of integrating the disclosed virtual display system in a vehicle.

### DETAILED DESCRIPTION

All illustrations of the drawings are for the purpose of describing selected versions of the present invention and are not intended to limit the scope of the present invention.

This disclosure extends previous methods, which produce a single, continuous lightfield that enables simultaneous detection of monocular depth by each eye of a viewer who is positioned within the intended viewing region, where both the monocular depth can be greater than the physical distance between the display and the viewer, and where the apparent size of the display (as perceived by the viewer) is larger or smaller than the physical size of the display. As disclosed herein, display systems are integrated with camera systems to provide immersive teleconferencing experiences and use optical and computational means. The methods in this disclosure can be used in arbitrarily engineered display and imaging systems. These include, but are not limited to, large-scale lightfield display systems that do not require glasses, display systems that do require glasses, display systems that curve in front of the face and are closer to the user, lightfield displays with fractional lightfield, any type of head-mounted displays such as augmented reality (AR) displays, mixed reality (MR) displays, virtual reality (VR) displays, and monocular and multifocal displays.

### Nomenclature

In this description, an “embodiment,” “one embodiment,” or similar words or phrases mean that the feature, function, structure, or characteristic being described is an example of the technique or invention introduced here. Such phrases in this specification do not necessarily all refer to the same embodiment. However, the embodiments referred to herein also are not necessarily mutually exclusive. All references to “user,” “observer,” or “viewer” pertain to either individual or individuals who would use the technique introduced here. All illustrations and drawings describe selected versions of the present invention and are not intended to limit the scope of the present invention.

The term “arbitrarily engineered” refers to being of any shape, size, material, feature, type or kind, orientation, location, quantity, components, and arrangements of single components or arrays of components that allow the present invention, or that specific component or array of components, to fulfill the invention's objectives and intents, or specific component's or components array's functionality. The term “optically coupled” refers to an element being adapted to impart, transfer, feed, or direct light to another element directly or indirectly.

In this disclosure, the “lightfield” at a plane refers to a vector field that describes the amount of light flowing in every or several selected directions through every point in that plane. The lightfield is the description of the angles and intensities of light rays traveling through or emitted from that plane. In this disclosure a “fractional lightfield” refers to a subsampled version of the lightfield such that full lightfield vector field is represented by a finite number of samples in different focal planes and/or angles. The term “concentric light field,” or “curving light field,” as used herein means a lightfield for which, for any two pixels of the display at a fixed radius from the viewer (called “first pixel” and “second pixel”), the chief ray of the light cone emitted from the first pixel in a direction perpendicular to the surface of the display at the first pixel intersects with the chief ray of the light cone emitted from the second pixel in a direction perpendicular to the surface of the display at the second pixel. A concentric lightfield produces an image that is focusable to the eye at all points, including pixels that are far from the optical axis of the system (the center of curvature), where the image is curved rather than flat, and the image is viewable within a specific viewing space (headbox) in front of the lightfield.

In this disclosure, “depth modulation” refers to the change, programming, or variation of monocular optical depth of the display or image. “Monocular optical depth” is the perceived distance, or apparent depth, between the observer and the apparent position of the source of light. It equals the distance to which an eye focuses to see a clear image. Thus, the monocular depth is the accommodation depth corresponding to the accommodation depth cue of the human vision system. Each eye separately experiences this depth cue, independent of the other eye.

For example, a point source of light emits light rays equally in all directions, and the tips of these light rays can be visualized as all lying on a spherical surface, called a wavefront, of expanding radius. In geometric optics, for example, free space or isotropic media, the wavefront is identical to the surface that is everywhere perpendicular to the light rays. When the point source is moved farther from an observer, emitted light rays travel a longer distance to reach the observer and therefore their tips lie on a spherical wavefront of larger radius and correspondingly smaller curvature, i.e., the wavefront is flatter. This flatter wavefront is focused by an eye differently than a less flat one. Equivalently, the light from a farther point source is focused differently than that from a closer point source. Consequently, the point source is perceived by an eye or a camera as being located at a farther distance, or deeper depth, to the eye or camera. Monocular optical depth does not require simultaneously both eyes, or stereopsis, to be perceived. An extended object can be considered as a collection of ideal point sources at varying positions and as consequently emitting a wavefront corresponding to the sum of the point-source wavefronts, so the same principles apply to, e.g., an illuminated object or emissive display panel. Evolution of a wavefront refers to changes in wavefront curvature due to optical propagation.

In this disclosure, the term “display” refers to an “emissive display,” which can be based on any technology, including, but not limited to, liquid crystal displays (LCD), thin-film transistor (TFT), light emitting diode (LED), organic light emitting diode arrays (OLED), active matrix organic light emitting diode (AMOLED), plastic organic light emitting diode (POLED), micro organic light emitting diode (MOLED), or projection or angular-projection arrays on flat screens or angle-dependent diffusive screens or any other display technology and/or mirrors and/or half-mirrors and/or switchable mirrors or liquid crystal sheets arranged and assembled in such a way as to exit bundles of light with a divergence apex at different depths or one depth from the core plane or waveguide-based displays. The display may be an autostereoscopic display that provides stereoscopic depth with or without glasses. It might be curved or flat or bent or an array of smaller displays tiled together in an arbitrary configuration. The display may be a near-eye display for a headset, a near-head display, or a far-standing display.

In some embodiments, the display is a folded display, which is a display that has substantially flat portions connected by bent portions. In some embodiments, the bent portions are turned off and emit no light. In this mode, the folded display serves as a replacement for multiple individual flat display panels. Thus a single, larger folded display is cheaper to fabricate or implement. The type of bending is arbitrary, subject to physical constraints such as the pixel-wise addressing electronics. A folded display differs from a curved display. A curved display has a smooth curvature throughout, i.e. it cannot be divided into regions of different curvatures, such as flat portions and bent portions.

A bent portion of a folded display has a small radius of curvature. The radius of curvature is at least 10 times smaller than a lateral dimension of a substantially flat portion. In some embodiments, the radius is 10 cm, 9 cm, 8 cm, 7 cm, 6 cm, 5 cm, 4 cm, 3 cm, 2 cm, 1 cm, 0.5 cm, or 0.1 cm.

In some embodiments, other elements are folded. For example, a folded reflector or semi-reflector comprises substantially flat reflectors or semi-reflectors continuously connected by a bent portion of reflector or semi-reflector.

A display system that produces a virtual image may be called a “virtual display system.” A “virtual image” is an image whereby the imaging-forming light rays corresponding to a given point of the image do not physically intersect. Rather, they diverge or are collimated. When the image-forming light rays are geometrically projected backward, their projections do intersect. This intersection point is the location of the virtual image. (In contrast, the image that is formed by physically intersecting light rays is a real image that may be projected onto a screen or other physical surface without any other focusing elements.)

In some embodiments, a virtual image is viewed by a viewer. The light forming the virtual image has traveled an optical distance corresponding to the monocular depth at which a viewer perceives the image. That is, the monocular depth is the depth at which the viewers' eyes accommodate (focus to). The geometric plane in space in which the virtual image is located is called the “focal plane.” In some embodiments, the monocular depth is modified by curved optical elements. In some embodiments, the focal plane is a non-flat geometric surface. A virtual image comprising a set of virtual images at different focal planes is called a “multifocal image.” A virtual image whose focal plane can be adjusted dynamically, e.g., by varying an optical or electrical property of the display system, is also called a multifocal image. A virtual display system that produces multifocal images may be called a “multifocal display system.” The monocular depth may be modified by elements with optical power, such as lenses or curved reflectors.

In some embodiments, a virtual image includes synthetic imagery resulting from combining different features or points of view of physical objects with data relevant to the context of the application in which the virtual image will be viewed by a viewer or an imaging system. A virtual image may be produced via a combination of hardware and software systems.

In some embodiments, a monocular depth is larger than the distance between the viewer and the light source. For example, the ratio between the monocular depth and the distance may be 1.1,1.5, 2, 2.5, 3, 4.5, or 5. In some embodiments, the ratio may lie within a range, such as 1.1-2, 1.5-3,or 2-5. In some embodiments, a monocular depth is dynamically adjustable by modifying a property of the virtual display system.

In some embodiments, the virtual image is visible by both eyes of a viewer anywhere within a continuous region called the headbox. The region spans a lateral dimension at least, e.g., 8 cm, 10cm, 15 cm, 20 cm, 30 cm, or 50 cm. A virtual image point being visible by both eyes means that light from that point enters both eyes simultaneously.

In some embodiments, the display system produces a real image in the space outside the display system. (A real image forms where the light rays physically intersect, such that a film placed at that location will record a (collection of) bright spot(s), corresponding to an image.) The light rays diverge beyond that intersection point, such that a viewer sees a virtual image. The focal plane of this virtual image will be the plane of the real image, so the virtual image will appear to the viewer as a floating, or hovering, image in front of the display panel. Such an image is called a “hovering real image.”

Throughout this disclosure, an “imaging sensor” captures light or a property of it when exposed to the light. Examples of such arbitrary image sensing technologies include complementary-symmetry metal-oxide-semiconductor (CMOS), single photon avalanche diode (SPAD) array, charge-coupled device (CCD), intensified charge-coupled device (ICCD), ultra-fast streak sensor, time-of-flight sensor (ToF), Schottky diodes, or any other light or electromagnetic sensing mechanism for shorter or longer wavelengths. An “imaging system” refers to any apparatus that acquires an image, which is a matrix of information about light intensity, phase, temporal character, spectral character, polarization, entanglement, or other properties used in any application or framework. Imaging systems include cellphone cameras, industrial cameras, photography or videography cameras, microscopes, telescopes, spectrometers, time-of-flight cameras, ultrafast cameras, thermal cameras, or any other type of imaging system. Imaging systems usually have an imaging sensor and a lens or lens group.

As used herein, the “aperture of a display system” is the surface where light exits a display system toward the exit pupil of the display system and to the outside world. The aperture is a physical surface, whereas the exit pupil is an imaginary surface that may or may not coincide with the aperture. The “aperture of an imaging system” is the area or surface where the light enters an imaging system after the entrance pupil of the imaging system travels toward a sensor. The entrance pupil is an imaginary surface or plane where the light first enters the imaging system.

“Aperture,” “an aperture optic,” or “aperture optics” correspond interchangeably to a set of optical elements located at an aperture surface. In some embodiments, the set contains only one element, such as a transparent window. Aperture optics protect the inside of an optical system from external contaminants and prevent unwanted light from entering the system. “Stray light” is unwanted light that interacts with a display or imaging system and travels along a substantially similar path as a desired image into a viewer or sensor. For example, stray light includes unwanted ambient light that enters a system and becomes visible to an observer or sensor, degrading image quality. Aperture optics prevents or mitigates stray light or its effects. In some embodiments, aperture optics includes a wave plate and a polarizer. In some embodiments, it includes an anti-reflection coating. In some embodiments, it includes an absorptive polarizer. In the context of stray-light mitigation, an aperture of a display system may also be called an “ambient light suppressor.” Though these are just examples, and any suitable configuration of elements may be used as an aperture optic.

As used herein, the term “chief ray” refers to the center axis of the light cone that comes from a pixel or a point in space through the center of the aperture. The “optic axis” or “optical axis” of a display (imaging) system is an imaginary line between the light source and the viewer (sensor) that is perpendicular to the surface of the aperture or image plane. It corresponds to the path of least geometric deviation of a light ray.

As used herein, the terms “field-evolving cavity” or “FEC” refer to a non-resonant (e.g., unstable) cavity that allows light to travel back and forth between its components to evolve the shape of the wavefront associated with the light in a physical space. One example of an FEC comprises two or more half-mirrors or semi-transparent mirrors facing each other and separated by a distance. As described herein, an FEC may be parallel to a display panel (in the case of display systems) or an entrance pupil plane (in the case of imaging systems). An FEC may be used for changing the apparent depth of a display or of a section of the display. In an FEC, the light bounces back and forth, or circulates, between components of the cavity. Each of these propagations is counted as a pass. For example, suppose there are two semi-reflective components for the FEC, one at the light source side and another one at the exit side. The first instance of light propagating from the first component to the second component is called a forward pass. When the light, or part of light, is reflected from the second component back to the first component, that propagation is called a backward pass, as the light is propagating backward toward the light source. In an FEC, a round trip occurs when the light completes one cycle and comes back to the first component. FECs can have infinitely many different architectures, but the principle is always the same. An FEC is an optical architecture that creates multiple paths for the light to travel, either by forcing the light to go through a higher number of round trips or by forcing the light from different sections of the same display to travel different distances before the light exits the cavity. If the light exits the cavity perpendicular to the angle it has entered the cavity, the FEC is referred to as an off-axis FEC or a “FEC with perpendicular emission.” In an FEC, the light is reflected back and forth, or is circulated, between the elements of the cavity. Each of these propagations is a pass. For example, an FEC may have a first element and a second element. The first instance of light propagating from the first element to the second element is called a forward pass. When the light, or a selected part of light, is reflected from the second element back to the first element, that propagation is called a backward pass, as the light is propagating backward toward the light source. In this cavity, a round trip occurs once the light completes one cycle (forward and backward pass) and returns to the first element. In some embodiments, a round trip occurs when light substantially reverses direction and is incident on an element more than once. The term “round trips” denotes the number of times that light circulates or bounces back and forth between the two elements of a cavity or the number of times light interacts with a single element.

In some embodiments, the light travels one round trip within the FEC. In some embodiments, the number of round trips may be 2, 3, 4, or 5. The number of round trips substantially determines the monocular depth perceived be a viewer. In some embodiments, a monocular depth is larger than the distance between the viewer and the light source. For example, the ratio between the monocular depth and the distance may be 1.1, 1.5, 2, 2.5, 3, 4.5, or 5. In some embodiments, the ratio may lie within a range, such as 1.1-2, 1.5-3, or 2-5. In some embodiments, a monocular depth is dynamically adjustable by modifying a property of the virtual display system.

The mechanism for introducing more round trips includes modifying the properties of the first and second element. For example, by using a different type of wave plate or an LC in the first element, the reflected polarization (after the first-round trip) can be configured differently, such that most of the light is reflected a second time by the second element. Further, the second element may also include a polarization-changing element, such as a wave plate or LC, to modify the polarization of the light that it reflects. Further, both the polarization changes and the reflectivity and transmittivity of these elements may be a function of angle. For example, either element may include a multilayer film. In such embodiments, because the angle of the light rays changes with each round trip, the light may be substantially transmitted by the second element after a desired angle is reached.

It is important to note that each point of the virtual image is visible by both eyes of a human viewer, i.e., that light rays from any given point of the virtual image enter both eyes simultaneously. The viewer's eyes may be located anywhere within a certain volume to see the virtual image. The depth of the virtual image is the depth each eye accommodates or focuses on. The volume is called the headbox, and it spans a lateral dimension. The lateral dimension may be, for example, at least 8 cm, at least 10 cm, at least 15 cm, at least 20 cm, or at least 30 cm. The distance between the display system and the nearest viewing position in the headbox may be, for example, 20 cm, 30 cm, 40 cm, 50 cm, 60 cm, 70 cm, 80 cm, 90 cm, or 100 cm. In some embodiments, the nearest viewing position is greater than 100 cm. This distance is in part limited by the viewing direction required to see the virtual image. Viewer 77 is understood to have his/her eyes within the headbox.

Further, the virtual image is an image whereby the imaging-forming light rays corresponding to a given point of the image do not physically intersect. Rather, they diverge or are collimated. When the image-forming light rays are geometrically projected backward, their projections do intersect. This intersection point is the location of the virtual image. (In contrast, the image that is formed by physically intersecting light rays is a real image that may be projected onto a screen or other physical surface without any other focusing elements.) In some embodiments, a viewer views a virtual image.

In the disclosed embodiments, light is profiled in different ways to enable the invention. “Angular profiling” is the engineering of light rays to travel in specified directions. Angular profiling may be achieved by holographic optical elements (HOEs), diffractive optical elements (DOEs), lenses, concave or convex mirrors, lens arrays, microlens arrays, aperture arrays, optical phase masks or amplitude masks, digital mirror devices (DMDs), spatial light modulators (SLMs), metasurfaces, diffraction gratings, interferometric films, privacy films, or other methods. “Intensity profiling” is the engineering of light rays to have specified values of brightness. It may be achieved by absorptive or reflective polarizers, absorptive coatings, gradient coatings, or other methods. The color or “wavelength profiling” is the engineering of light rays to have specified colors, or wavelengths. It may be achieved by color filters, absorptive notch filters, interference thin films, or other methods. “Polarization profiling” is the engineering of light rays to have specified polarizations. It might be achieved by metasurfaces with metallic or dielectric materials, micro-or nanostructures, wire grids or other reflective polarizers, absorptive polarizers, quarter-wave plates, half-wave plates, 1/x waveplates, or other nonlinear crystals with an anisotropy, or spatially profiled waveplates. Components can be arbitrarily engineered to deliver the desired profile.

As used herein, “arbitrary optical parameter variation” refers to variations, changes, modulations, programing, and/or control of parameters, which can be one or a collection of the following variations: optical zoom change, aperture size or brightness variation, focus variation, aberration variation, focal length variation, time-of-flight or phase variation (in the case of an imaging system with a time-sensitive or phase-sensitive imaging sensor), color or spectral variation (in the case of a spectrum-sensitive sensor), angular variation of the captured image, variation in depth of field, variation of depth of focus, variation of coma, or variation of stereopsis baseline (in stereoscopic acquisition).

The terms “active design,” “active components,” or, generally, “active” refer to a design or a component with optical properties that can be varied with an optical, electrical, magnetic, or acoustic signal. In some embodiments, the active component is an electro-optical component. “Passive designs” or “passive components” refer to designs that have no active component other than a display.

The “polarization state” of a light ray or light wave corresponds to its character of polarization. It may be quantified by a Jones vector, a Stokes vector, a position on the Poincaré sphere, and the like. Included in the polarization state is the degree of polarization, which quantifies how strongly or randomly the light is polarized. Each ray of a lightfield may have a different polarization. In some embodiments, the polarization state of a light ray is quantified by its polarization relative to the surface of a component.

Throughout this disclosure the “pass angle” of a polarizer is the angle at which normally incident light passes through the polarizer with maximum intensity. Two polarizers that are “cross polarized,” are such that their pass angles are orthogonal. In some embodiments, the term describes orthogonal polarization of some light relative to other light or to a polarizer's pass angle.

Throughout this disclosure, the term “GRIN material,” or “GRIN slab,” refers to a material that possesses a graded refractive index, which is an arbitrarily engineered material that shows a variable index of refraction along a desired direction. The variation of the refractive index, direction of its variation, and its dependency with respect to the polarization or wavelength of the light can be arbitrarily engineered.

The light efficiency or optical efficiency is the ratio of the light energy the reaches the viewer to the light energy emitted by an initial display.

A “gesture” is a motion, facial expression, or posture orientation of a user, which are normally interpreted by a person or by a computer to indicate a certain desired change, emotion, or physical state. They are typically on a time scale observable by a human being. Micro-gestures are motions, expressions, or orientations that occur within a fraction of a second. They are usually involuntary and indicate similar features as gestures. They can include brief shifts in eye gaze, finger tapping, or other involuntary actions. Gestures may be captured by a camera and identified or classified by a deep learning algorithm or convolutional neural network.

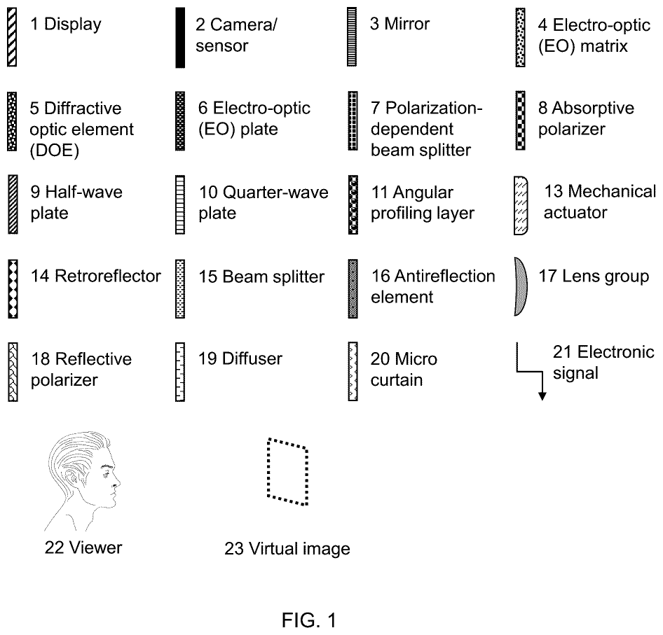

FIG. 1 depicts icons representing elements that are used throughout all the disclosure figures and serve as dictionary elements or glossary elements.

Element 1 is the schematic representation of a display.

Element 2 is a camera. A camera is an imaging system and comprises a lens group to focus light and form a real image onto an imaging sensor or film. In some embodiments, for example, a camera is used to capture information about a user or a user's environment. A camera may operate in the visible spectrum. An RGB camera is an example of a color camera. Generally a color camera records an image by assigning intensity values to each pixel, each pixel sensitive to a color (or wavelength). In some embodiments, the color camera has red (R), blue (B), and green (G) pixels. A camera may alternatively operate in the infrared (IR) part of the electromagnetic spectrum. In some embodiments, multiple cameras, a camera array, or a camera system capture an image. In some embodiments, a depth camera captures information about depth or sense gestures and poses and they can be of any type. In this disclosure, a “depth camera” is a camera that records the distance between the camera and the distance to an object point. In some embodiments, an RGBD camera captures a color image and a depth map. A depth camera may use active illumination or ambient light, and it can include multiple cameras. Stereo cameras, light detection and ranging (LIDAR) cameras, and time-of-flight cameras are examples of active depth cameras. A depth camera can also use optical coherence tomography sensing (i.e., autocorrelation). It can use infrared (IR) illumination to extract depth from structure or shading. Depth cameras can incorporate gesture recognition or facial recognition features. Depth can also be estimated from conventional cameras or a plurality of conventional cameras through, for example, stereo imaging. A camera system can include any combination of these cameras.

In some embodiments, element 2 depicts a generic sensor, which can be an imaging sensor, a temperature sensor, a pressure sensor, a motion sensor, and the like. In some embodiments, the sensor is an ambient-light sensor to measure the amount of ambient light present and output a corresponding electronic signal. An ambient light sensor may be a photodiode, a power meter, an imaging sensor, and the like. In some embodiments, a sensor is an imaging sensor as part of an imaging system. The unifying feature of these examples is that the sensor collects information about the outside environment.

Element 3 is the schematic representation of a mirror, which specularly reflects light. In some embodiments, the mirror comprises a reflective metal or a dielectric multilayer mirror. In some embodiments, a mirror relies on total internal reflection (TIR). Mirrors may be curved or flat. The term “reflector” is used interchangeably.

Element 4 represents an electro-optic (EO) matrix. This is an example of an addressable matrix. The pixels of the of the LC matrix modulate the polarization of the incident light, such that a polarizer converts the polarization changes to intensity changes to produce an image.

Element 5 is a diffractive optical element (DOE), which has microstructure to produce diffractive effects. The DOE can be of any material. In some embodiments, a DOE is a Fresnel lens.

Element 6 is an electro-optic (EO) plate such as a liquid crystal (LC) slab or plate. EO materials include LCs; liquid crystal as variable retarder (LCVR); or piezoelectric materials/layers exhibiting Pockel's effects (also known as electro-optical refractive index variation), such as lithium niobate (LiNbO₃), lithium tantalate (LiTaO₃), potassium titanyl phosphate (KTP), strontium barium niobate (SBN), and β-barium borate (BBO), with transparent electrodes on both sides to introduce electric fields to change the refractive index. EO materials can be arbitrarily engineered. In the “ON” state, the LC plate rotates the polarization of the light that passes through it. When the EO plate is an LC plate, in the “OFF” state, the state of the light polarization is unchanged upon transmission through the layer. In some embodiments the LC is a nematic twisted crystal.

Element 7 is a polarization-dependent beam splitter (PBS). A PBS reflects light of one polarization and transmits light of the orthogonal polarization. A PBS can be arbitrarily engineered and made using reflective polymer stacks or nanowire grids or thin film technologies. In some embodiments, a PBS is interchangeable with a reflective polarizer.

Element 8 is an absorptive polarizer, which transmits light polarized along its pass angle and absorbs cross polarized light.

Element 9 is a half waveplate (HWP), which produces a relative phase shift of 180 degrees between perpendicular polarization components that propagate through it. For linearly polarized light, the effect is to rotate the polarization direction by an amount equal to twice the angle between the initial polarization direction and the axis of the waveplate. In some embodiments, horizontally polarized light is converted to vertically polarized light, and vice versa, after transmission through an HWP.

Element 10 is generic quarter waveplate (QWP), which produces a relative phase shift of 90degrees. It transforms linearly polarized light into circularly polarized light, and it transforms circularly polarized light into linearly polarized light.

Element 11 is a generic angular profiling layer, which is an arbitrarily engineered layer to produce a specified angular distribution of light rays. In some embodiments, it allows the transmission of rays within a certain range of incident angles, whereas rays outside such a range of angles are blocked. In some embodiments an angular profiling layer is a directional film or layer. This element selectively transmits light rays that are oriented at angles within a specified angular range and blocks light rays directed outside that range. For example, the directional film may transmit light rays that are incident within a range from zero to 10 degrees, zero to 20 degrees, zero to 30 degrees, zero to 40 degrees, zero to 50 degrees, or zero to 60 degrees. The directional film does not provide optical (focusing) power. In some embodiments, the directional film transmits an angular range that does not start at zero degrees. The directional film may be placed after a display.

Element 13 is a mechanical actuator that can physically move the elements to which are connected via an electrical or other type of signal.

Element 14 is a retroreflector, which is a mirror that reflects light rays in the exact same directions along which they are incident. The retroreflector can be fabricated with microstructures such as microspheres, micro corner cubes, or a stack of metasurfaces, or it can be a nonlinear element. A phase conjugating mirror can function as a retroreflector.

Element 15 represents a generic beam splitter, which partially reflects and partially transmits light. The ratio of reflected light to transmitted light can be arbitrarily engineered. In some embodiments, the transmission-to-reflection ratio is 50:50. In some embodiments, the transmission-to-reflection ratio is 70:30. A beam splitter is a semi-reflective layer that reflects a certain desired percentage of the intensity and transmits the rest of the intensity. A simple example of a beam splitter is a glass plate with a semi-transparent silver coating or dielectric coating on it, such that it allows 50% of the light to pass through it and reflects the other 50%. The term “semi-reflector” is used interchangeably.

Generally, both mirrors and beam splitters are used to direct light along a proscribed path in a display system. Both rely on specular reflection because their surfaces are smooth on the order of a wavelength. The term “specular reflector” therefore refers to both mirrors and beam splitters. The main difference is only the relative amount of light that is reflected. For example, with a perfect mirror, all the light is reflected, whereas in a standard beam splitter, about half the light is reflected. Though, a beam splitter may be designed to reflect other fractions of the light such as, for example, about 25% or 75%. How much light is reflected, the reflectance, may also vary by wavelength or polarization.

If light passes along the same portion of an optical path more than once the optical path is said to fold onto itself. For example, light may be normally incident on a mirror, beam-splitter, reflector, or semi-reflector and the reflected light at least initially reverses along the same optical path as the incident light. If light were to go out from a light source and back to the light source along the exact same optical path it would be fully folded onto itself. If the light only repeats a portion of the optical path the optical path is said to be partially folded onto itself or equivalently that a portion of the optical path is folded onto itself.

Element 16 is an antireflection (AR) element that eliminates reflections of light incident on its surface. A microstructure such as a nano-cone layer may be an AR element. In some embodiments an AR element is a thin-film coating.

Element 17 represents a lens group, which consists of one or multiple lenses of arbitrary focal length, concavity, and orientation. In some embodiments, a lens group forms a real image on an imaging sensor.

Element 18 is a generic reflective polarizer, which transmits light polarized along its pass angle and reflects cross polarized light. A wire grid polarizer (a reflective polarizer made with nano wires aligned in parallel) is an example.

Element 19 is a generic diffuser, which scatters light in a random or semi-random way. A diffuser can be a micro-beaded element/array or have another microstructure. Diffusers may reflect scattered light or transmit scattered light. The angular profile of the light may be arbitrarily engineered. In some embodiments, light scattered by a diffuser follows a Lambertian profile. In some embodiments, the light scattered forms a narrower profile.

Element 20 is a micro-curtain, which redirects light into specified directions or shields light from traveling in specified directions. A micro curtain can be made by embedding thin periodic absorptive layers in a polymer or glass substrate, or it can be made by fusing thin black coated glass and cutting cross-sectional slabs.

Element 21 represents an electronic signal that is used in the electrical system that accompanies the display system to modulate the optical elements or provide feedback to the computer.

Element 22 depicts a generic viewer or user of the invention described herein. The light from a point of a virtual image with monocular enters both eyes of the viewer.

Element 23 represents a virtual image, which is the position at which a viewer will perceive an image created by the display systems disclosed herein.

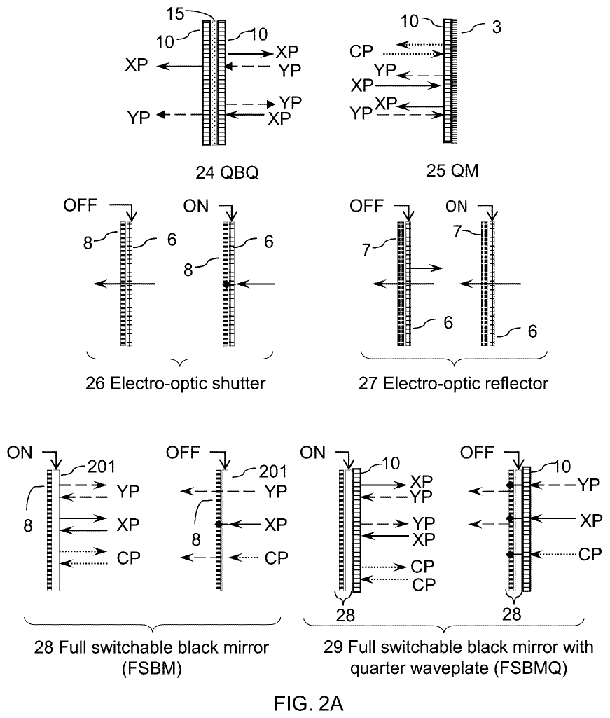

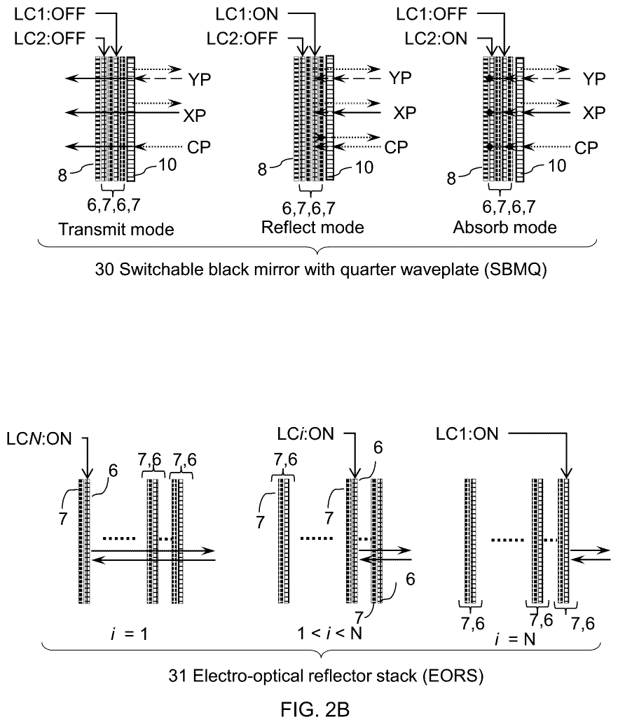

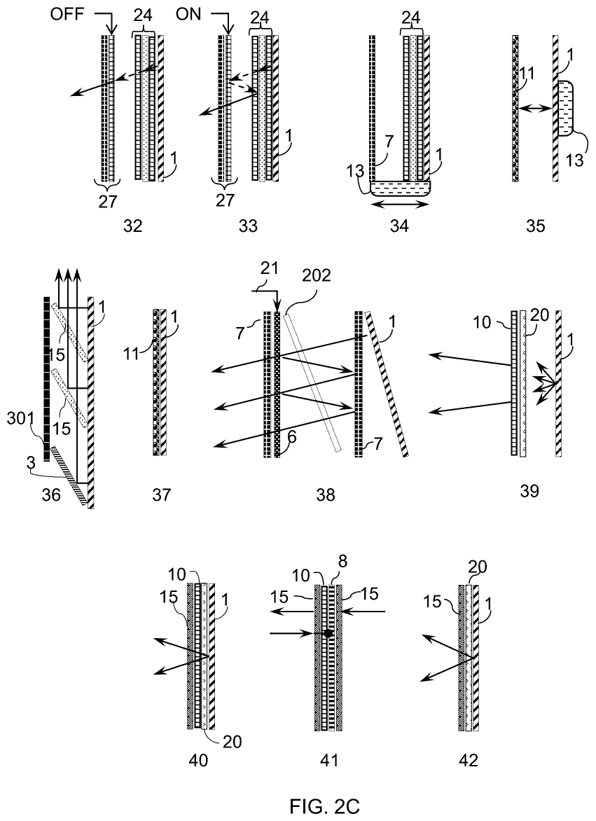

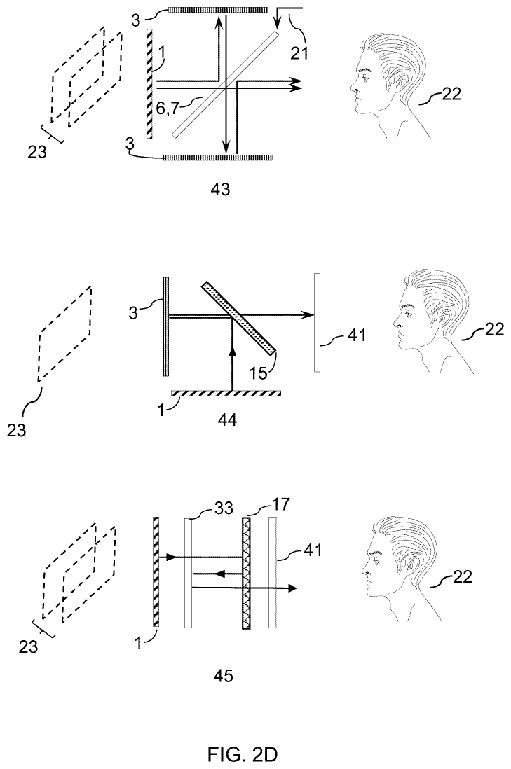

FIGS. 2A through 2D show how components of FIG. 1 can be combined to produce functional elements, architectures, subassemblies, sub-systems, and FECs. In some embodiments, these are integrated into a single, monolithic element, e.g., where a substrate is coated with various films or coatings. In some embodiments, they may be discrete components arranged with or without air gaps between them. In FIG. 2A, a QBQ 33 comprises a QWP 10, a beam splitter 14, and another QWP 10. Light incident on a QBQ is partially reflected and partially transmitted, and the QBQ acts as a HWP for both the reflected and transmitted portions, converting x-polarized light (XP) into y-polarized light and vice versa. In some embodiments, the beam splitter is a PBS. A QM 34 comprises a QWP 10 and a mirror 3. It reflects all light, and it converts x-polarized light into y-polarized light and vice versa (or, equivalently, horizontally polarized light into vertically polarized light). It does not change the polarization state of circularly polarized light.

An electro-optic shutter 35 comprises an LC plate 21 and an absorptive polarizer 8. When the LC plate is ON, it rotates the polarized incident light such that it is aligned perpendicular to the absorptive polarizer and is absorbed by it. When the LC plate is OFF, it leaves the polarization unchanged and parallel to the absorptive polarizer which transmits it. An electro-optic reflector 36 comprises an LC plate 21 and a PBS 7. When the LC plate is ON, it rotates the polarization such that it aligned along the transmit orientation of the PBS. When the LC layer is OFF, the light passing through it is aligned such that the PBS reflects it.

A fully switchable black mirror (FSBM) 37 comprises an absorptive polarizer 8 and a full switchable mirror 201, which may be an EO material. In the ON state, the full switchable mirror 201 is on and reflects light of all polarizations. In the OFF state, the switchable mirror transmits the light, and an absorptive polarizer 8 extinguishes x-polarized light, transmits y-polarized light, and transmits only the y-component of circularly polarized light. A full switchable black mirror with quarter waveplate (FSMBQ) 38 comprises an FSBM 34 and a QWP 10. In the ON state, it reflects all light and interchanges x-polarized with y-polarized light (and vice versa). It reflects circularly polarized light without changing the polarization. In the OFF state it extinguishes circularly polarized light, transmits y-polarized light, and coverts x-polarized light into y-polarized light and transmits the result.

Shown in FIG. 2B are two switchable reflective stacks. A switchable black mirror with quarter waveplate (SBMQ) 39 comprises a QWP 10, followed by two alternating layers of LC plates 21 and PBSs 7, and finally one absorptive polarizer 8. The difference between the FSBMQ and the SBMQ is their corresponding polarization dependence. In the former, the total reflectivity of the material is changing, agnostic to the polarization of the incident light, whereas the latter element produced a polarization-dependent reflectivity. For the SBMQ 39, when both LC plates are OFF (“transmit mode”), all incident polarizations transmit an x-polarized component; incident linear polarization reflect circular polarization. Incident circular polarization reflects light that depends on whether it is right-or left-circularly polarized. When the first LC plate is ON and the second OFF (reflect mode), all light is reflected as circularly polarized. When the plate LC plate is OFF and the second LC is ON (absorb mode), incident light that strikes the absorptive layer and is extinguished, and no light is transmitted through the layers.

An electro-optical reflector stack (EORS) 40 comprises a stack of N alternating PBS 7 and LC plates 21. All but one LC plate is in the OFF state, and the LC plate that is in the ON state reflects the incident x-polarized light. All other layers transmit light. By varying which LC layer is in the ON state, the EORS modulates the optical depth or optical path or the length that the light must travel through the stack before it is reflected by a cross-polarized PBS layer next to the ON LC layer. In some embodiments the LC plates and PBSs are configured to reflect y-polarized light.

Shown in FIG. 2C are further combinations of elements and how those combinations are used in conjunction with a display. In some embodiments, these form an FEC. In some embodiments, they serve as pre-cavity optics or post-cavity optics to profile the light before or after, respectively, traveling through an FEC. A switchable FEC in the OFF state 41 and in the ON state 42 is optically coupled to a display. Light from the display passes through a QBQ 33 followed by an electro-optic reflector 36. In the OFF state, the light directly exits the device to be viewed by an observer. In the ON state, the light is forced to travel one round trip in the cavity, and the displayed image appears to be deeper compared to the actual location of the display. In some embodiments, the monocular depth of the resulting image is approximately twice as far as that of the display itself.

A mechanically actuated FEC 43 is coupled to a display 1. The display sends light through a QBQ 33 and a PBS 7 set on a mechanical actuator 29. The actuator shifts the set of elements to create longer or shorter optical path lengths for the light and hence shorter or longer monocular depths. In a second mechanically actuated system 44, the display 1 itself is coupled to a mechanical actuator 29. The actuator can shift the display relative to an angular profiling element 11 to force the light to change directionality or to become collimated. In some embodiments, the angular profiling layer is a lenslet array such that the mechanical movement of the display changes the object distance and therefore impacts the collimation. In some embodiments, the display is “macro-formed,” meaning it may have mechanical waves or bends induced onto it by the mechanical actuators so that the directionality or collimation of the light that comes out of the angular lenslet array is impacted in a desired way. In some embodiments other elements, such as a beam splitter or mirror, are macro-formed.

In some embodiments, the display is mechanically shifting because of the actuator's motion along a translational axis to impact the directionality of the exit light from the apertures. The mechanical actuation mechanism may be arbitrarily engineered. In some embodiments, the mechanical actuator is an array of ultrasonic transducers; in some embodiments, the mechanical translation is performed by a high rotation-per-minute brushless motor; in some embodiments, the mechanical movements are delivered via a piezo-or stepper motor-based mechanism.

A segmented FEC 45 is optically coupled to a display 1 that is partitioned into segments, i.e., it is a segmented display. Light from the bottom segment is reflected by a mirror 3, and light from the upper segments is reflected by subsequent beam splitters 14. An absorptive matrix 12 absorbs unwanted stray light. In some embodiments the absorptive matrix is a uniform attenuator to substantially absorb all the light incident on it uniformly across its surface. This is an example of an off-axis FEC. In some embodiments, the FEC produces a multifocal image. The FEC can be arbitrarily engineered to produce the desired number of focal planes.

An angular-modified display 46 consists of display 1 layer followed immediately by an angular profiling element 11, which may be a directional film here. The angular profiling layer might be a lenticular lens array to provide stereopsis to the viewer, or it might be a lenslet array or any other angular profiling layer to provide autostereoscopic 3D or provide different images to different angles. The angular profiling layer is an example of pre-cavity optics.

An example of a tilted-component FEC 47 may be coupled to a tilted display 1, which sends light into the FEC comprising an “internal polarization clock” whose ends are composed of PBSs 7. In between the PBSs 7 is an EO material 6 that acts as a polarization rotator and a birefringent plate 26, such that different angles of propagation result in different phase retardation of polarization. Another EO material 6 acts as shutter element that uses an electronic signal 30 that turns the light into a desired polarization so that only one of the round trips are allowed to exit the cavity, and the transmitted light has traveled a desired optical path or depth. This is a representation of a coaxial FEC with polarization clocks and segmented gated apertures with desired gating mechanisms. In some embodiments, each of these elements is segmented, such that light from different portions of a segmented display travel different distances.

An aperture optic 48 lies between a viewer 29 and a component 203 of the display system. In some embodiments, the component is an FEC. The aperture serves to take an ambient light ray 202A that is incident on it and modify it. In some embodiments, the transmitted light ray 203 has a different amplitude or direction. In some embodiments, the incident light ray is fully extinguished, and the aperture optic removes all or a substantial amount of the ambient light incident on it. In some embodiments, the aperture optic includes a polarizer. In some embodiments, the aperture optic includes an antireflection element. In some embodiments, the aperture optic is just a transparent material, such as a piece of glass.

A modified display 49 is a display 1 followed by a micro-curtain 19 and a QWP 10 to function as pre-cavity optics. This allows desired profiling of the light of the display. The pre-cavity optics can adjust the polarization, angular distribution, or other properties of the light entering the cavity. Another pre-cavity subassembly 50 shows of a stack of elements: a display 1, a QWP 10, a micro-curtain layer 19, and an antireflection element 15. This subsystem is used in many disclosed systems and is categorized as a display. The micro curtain can be arbitrarily engineered, and it allows for control of the directionality of the light and the visibility of the display. The AR layer allows for reduction of ambient or internal reflections of the systems that use this subcomponent. In some embodiments, the AR element is a coating on substrate.

Subassembly 51 is a sub-assembly consisting of an AR element 15 and an absorptive polarizer 8 on one side facing a viewer and outside world, and a QWP 10 another optional AR element 15 or film on the side that faces the display from which light exits. In some embodiments, the AR element is a coating on substrate. In this disclosure, 48 is an example of aperture optics called an ambient light suppressor. In some embodiments, the ambient light suppressor is the final set of optical elements that the light experiences before exiting the display system. In some embodiments, the ambient light suppressor further comprises a directional film or angular profiling layer to produce angular profiling of the light exiting the system. Subassembly 52 is a subassembly of display 1 with micro curtain layer 19 and an AR element 15 on top.

An example of an off-axis multifocal FEC 53 comprises two mirrors 3 on the top and bottom, a display 1 at the back, and an angled PBS 7 with LC plate 21 in the middle such that the electronic signal 30 to the LC can change the length that the light must travel before it exits the cavity. In some embodiments, a stack of such angled PBS-on-LC splitters such that the length of the light travel can be programmed or controlled in multiple steps. In some embodiments, the mirror is a QM to rotate the polarization of the light. A viewer 29 sees a plurality of virtual images 31. The viewer perceives the depth to be the monocular depth of the image, and light from every point of the image enters both eyes.

A simple off-axis FEC 54 comprises a display 1 coupled to display optics. The display light is reflected by a beam splitter 14, then reflected by a mirror 3, and then transmitted through the same beam splitter. The light may optionally pass through an aperture optic 48 to suppress stray light before being seen by a viewer. A viewer 29 sees a virtual image 31. The viewer perceives the depth to be the monocular depth of the image, and light from every point of the image enters both eyes. In some embodiments, the beam splitter is polarization dependent and additional wave plates are included to perform polarization profiling of the light for increased light efficiency.

A coaxial FEC 55 shows display 1 which passes through a QBQ 33; the light is reflected by a reflective polarizer 17, then reflected by the same QBQ. This reflection by the QBQ rotates the polarization by 90 degrees, so that it passes through the reflective polarizer. An aperture optic 48 may optionally filter out stray light before being viewed by a viewer. A viewer 29 sees on or a plurality of virtual images 31. The viewer perceives the depth to be the monocular depth of the image, and light from every point of the image enters both eyes.

Although the embodiments described herein refer to an automobile or car, the vehicle can take on other forms, including, for example and not limitation, a car, a truck, a bus, a motorcycle, a tricycle, a tank, an aircraft, or a water vessel.

It is important to note that each point of the virtual image is visible by both eyes of a human viewer, i.e., that light rays from any given point of the virtual image enter both eyes simultaneously. The viewer's eyes may be located anywhere within a certain volume to see the virtual image. The depth of the virtual image is the depth each eye accommodates or focuses on. The volume is called the headbox, and it spans a lateral dimension. The lateral dimension may be, for example, at least 8 cm, at least 10 cm, at least 15 cm, at least 20 cm, or at least 30 cm. The distance between the display system and the nearest viewing position in the headbox may be, for example, 20 cm, 30 cm, 40 cm, 50 cm, 60 cm, 70 cm, 80 cm, 90 cm, or 100 cm. In some embodiments, the nearest viewing position is greater than 100 cm. This distance is in part limited by the viewing direction required to see the virtual image. Viewer 77 is understood to have his/her eyes within the headbox.

Further, the virtual image is an image whereby the imaging-forming light rays corresponding to a given point of the image do not physically intersect. Rather, they diverge or are collimated. When the image-forming light rays are geometrically projected backward, their projections do intersect. This intersection point is the location of the virtual image. (In contrast, the image that is formed by physically intersecting light rays is a real image that may be projected onto a screen or other physical surface without any other focusing elements.) In some embodiments, a viewer views a virtual image.

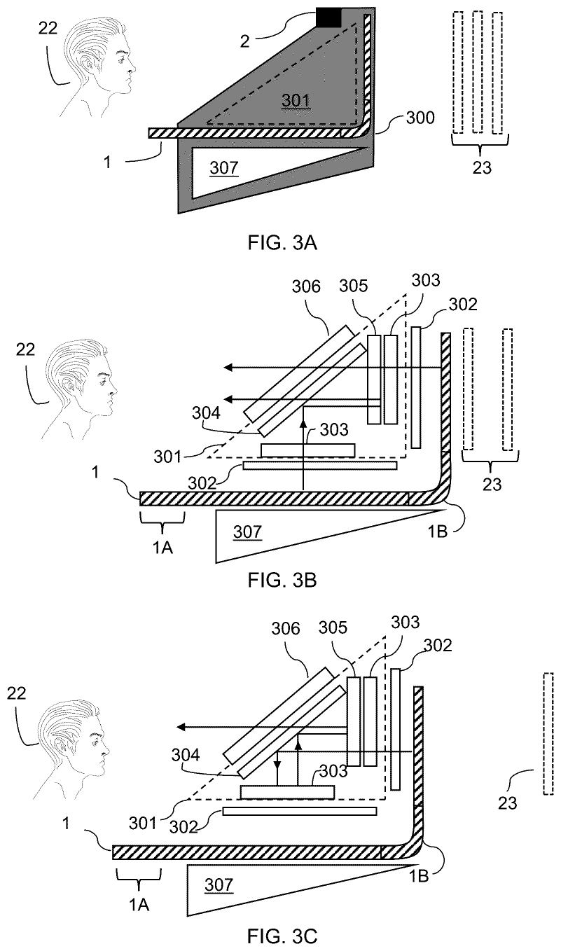

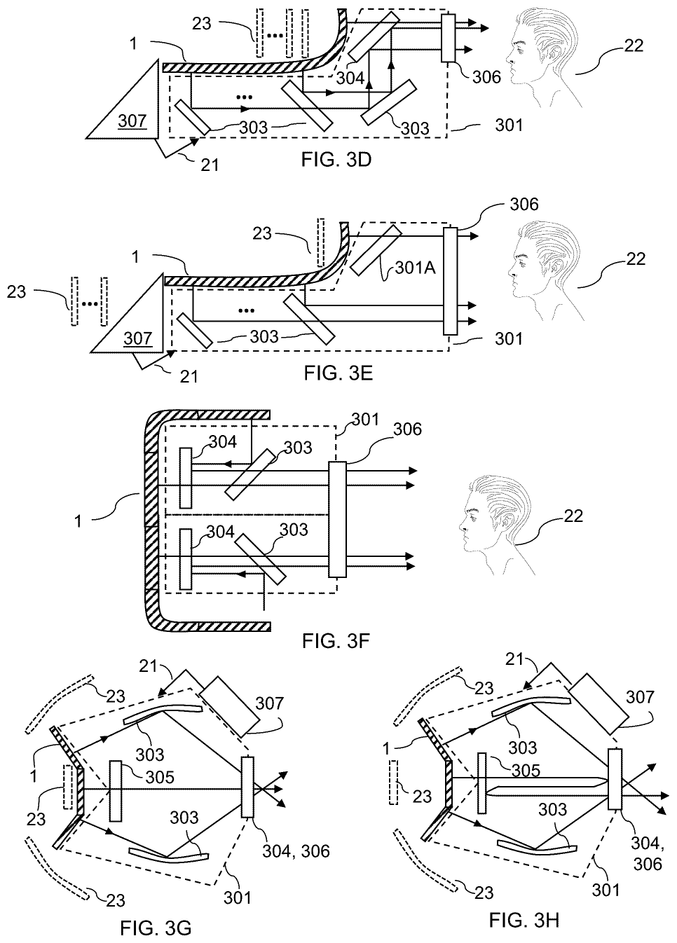

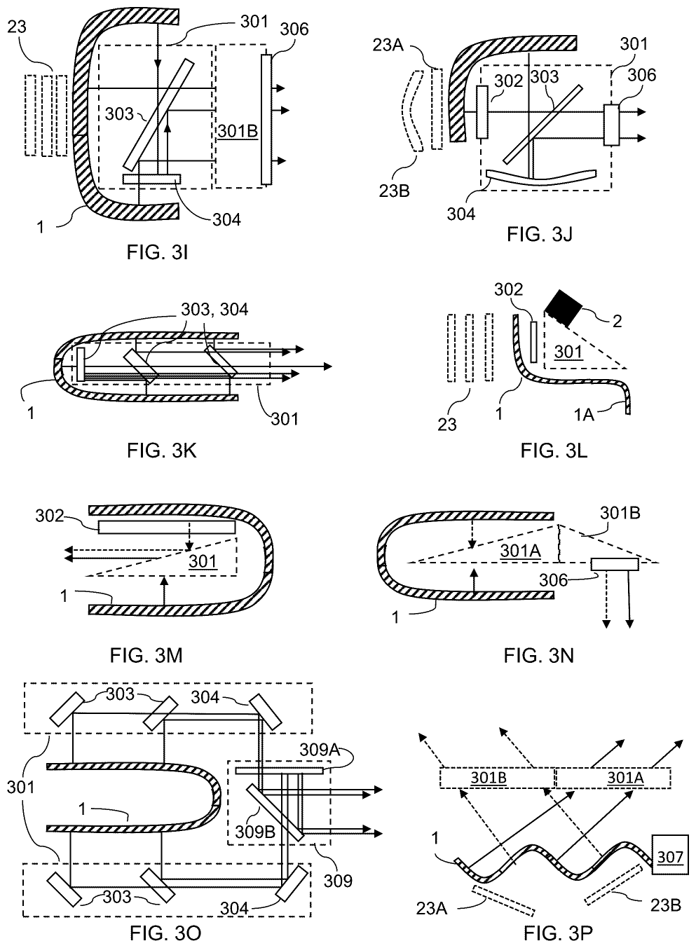

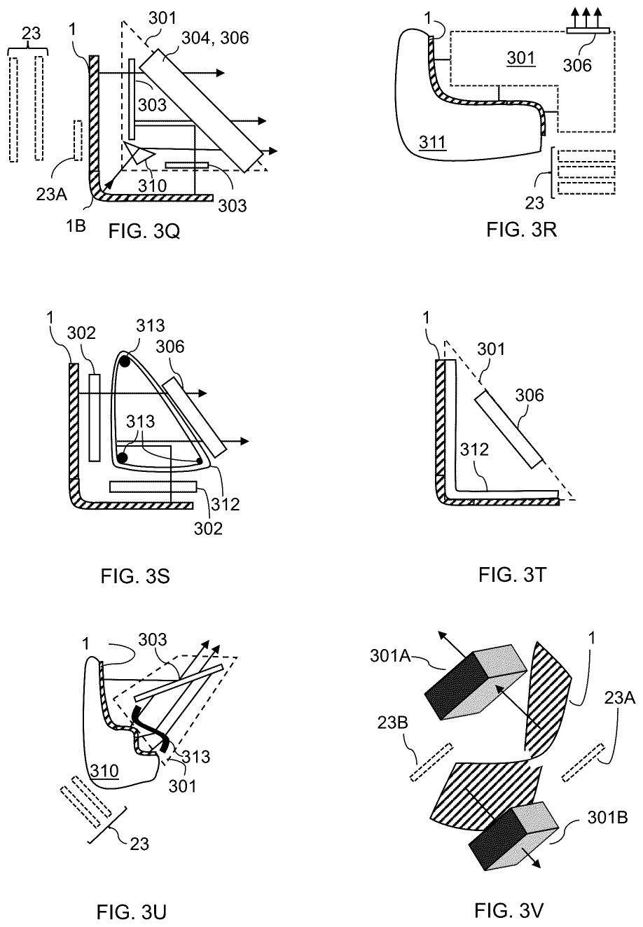

FIGS. 3A through 3V depict a set of embodiments of virtual display systems wherein the display panel is a folded display. In FIG. 3A, a display system 300 comprises a display 1 which is bent such that two flat regions are oriented at 90 degrees relative to each other and connected by a bent portion. The display emits light into a field-evolving cavity 301 (represented by the volume/area shown by the enclosing dashed line), which directs light to a viewer 22 who sees a virtual image 23. The display system, the display, or a component of the display system may be controlled electronically by a circuit block 307. In some embodiments, a camera 2 detects information about the viewer and uses that information to modify the display content. For example, the camera may be an eye tracking or pose tracking camera that captures how fatigued the viewer is or how the viewer's eyes may be fixating in a certain direction. If the viewer is the driver of the vehicle, the display may display content suggesting that the driver take a break or refocus attention to the road.

FIG. 3B depicts an embodiment in which a display 1 is a folded display that includes a bent portion 1B and an extended portion 1A. The shape of the display in this embodiment is an L-shape. The other parts of the display emit light through pre-cavity optics 302, which may comprise a directional film. The light then enters a field-evolving cavity. Each portion of light passes through a respective first specular reflector. All the light is then incident on a second specular reflector 304. In some embodiments, the first specular reflector 303 and the second specular reflector 304 are polarization dependent. In some embodiments, they are semi-reflectors or partial reflectors. For example, the first specular reflector 303 may be a polarization-changing semi-reflector, which is an element that transmits at least a portion of the light incident on it and further converts the incident light's polarization from one state into another. In some embodiments, a polarization-changing semi-reflector comprises a first wave plate and a beam. In some embodiments, the wave plate is a quarter-wave plate. If linear polarized light is incident on this polarization-changing semi-reflector, the light that is transmitted will be circularly polarized.

The states of polarization under consideration may be linear polarization, circular polarization, or elliptical polarization. In some embodiments, the degree of polarization is included in the state of polarization.

In some embodiments, the optical properties of the first specular reflector 303 or second specular reflector 304 are controlled by an electronic signal. For example, the above mentioned waveplate in the polarization-changing specular reflector may be an electro-optic material, such as a liquid crystal (LC), e.g., a nematic LC or a cholesteric LC. When a first voltage is applied to it, it may transmit light without changing its polarization (thus preserving the polarization), When a second voltage is applied to it, it may change the polarization from a first state to a second such as a conversion from horizontally polarized light to vertically polarized light. The voltage values may be arbitrarily engineered and include 0 V. For example, if the first specular reflector 303 comprises a wave plate, a beam splitter, and a liquid crystal plate, then the applied voltage impacts how the polarization of transmitted and reflected light is changed. At one voltage, transmitted polarization may rotate 90 degrees. At a second voltage, it may rotate 0 degrees. At a third voltage, incident linear polarization may be converted into circular polarization. Thus, the type of wave plate and the configuration of an LC can impact the transmitted polarization. Consequently, the transmitted light will interact differently with the second specular reflector 304.

In some embodiments, one of the portions of light also passes through a secondary element 305, which may be an EO element 6 of FIG. 1, such as a liquid crystal. In some embodiments, the secondary element is a birefringent material for which the refractive index experienced by light in it depends on its direction and polarization.

In some embodiments, different portions of light from the display travel different optical paths within the FEC 301 to produce a virtual image that comprises multiple focal planes, i.e., is a multifocal virtual image.

In some embodiments, the aperture optic comprises a reflective polarizer, an absorptive polarizer, and an antireflection layer. In some embodiments, the aperture optic comprises a quarter-wave plate.

In some embodiments, each of the first specular reflectors 303 comprise a beam splitter and a wave plate, which may be a quarter-wave plate. In some embodiments, the second specular reflector 304 also comprises a beam splitter and a quarter-wave plate. In some embodiments, a reflective polarizer is included in either the aperture optic 306 or the second specular reflector 304. In some embodiments, light from the display is linearly polarized. For example, in some embodiments, linear polarized light is emitted from the side portion of the display 1, is transmitted and converted into circular polarization by the first specular reflector 303, is transmitted and converted to an orthogonal polarization by the second specular reflector 304, such that the linear polarization is aligned with a reflective polarizer with either the second specular reflector 303 or the aperture optic 306 and exits the system. Similarly, in some embodiments, linear polarized light is emitted from the bottom of the display, is transmitted and converted into circular polarization by the first specular reflector 303, is converted again into linear polarization by the second specular reflector 304 but is oriented to be reflected by the reflective polarizer of the second specular reflector 303 or the aperture optic 304. It then passes through the second specular reflector 303, reflected by a first specular reflector 303, and retransmitted through the second specular reflector 304, but now is aligned with a reflective polarizer to exit the system.

In some embodiments, the vertical first specular reflector 303 comprises a LC plate that can rotate the polarization of the linear polarized light from the display by 90 degrees when a certain voltage is applied. This serves to change the optical path of the light from the side of the display 1 such that it results in a virtual image at a different monocular depth that when the LC plate has a different voltage applied.

FIG. 3C shows the same embodiment as shown in FIG. 3B except that the electrical state of one of the specular reflectors 303 (or the secondary element) is changed. In this case, light from the vertical portion of the display 1 travels through the pre-cavity optics 302 into the FEC 301, through a first specular reflector 303 and optionally through a secondary element 303. Because the electrical state is different, the polarization of the light is modified to be reflected by the second semi-reflector 304, then reflected by a first semi-reflector 303 at the bottom of the FEC 301, reflected again by the second semi-reflector 304, reflected by the first semi-reflector 303 and finally transmitted to through the second semi-reflector 304 and aperture optic 306.

FIG. 3D shows a display 1, which is a bent L-shaped display. L-shaped means that there are two substantially flat portions of the display smoothly connected by a bent portion. The term “substantially flat” means that the radius of curvature in any direction is at least 3 times larger than the corresponding lateral extent of the display. Though, in some embodiments, the substantially flat portions are flatter (e.g., 5, 10, 15, 20, 100 times larger radii than corresponding lateral extent.) The display emits light into an FEC 301. The long part of the display is partitioned into a plurality of segments, each showing a different display content. Each portion interacts with at least one first semi-reflector 303 to guide the light to a second semi-reflector 304 where it exits the cavity through an aperture optic 306 to be seen by a viewer 22. The short part of the display passes directly through the second semi-reflector, and through the aperture optic 306 to the viewer 22. The result is a virtual image that is a multifocal image, where each focal plane corresponds to a display content on the display 1. The display is controlled by an electronic signal 21 generated by a circuit block.

FIG. 3E shows a similar embodiment, in which the display 1 is an L-shaped folded display. The light from the long portion of the display enters at FEC 301, travels through a plurality of first semi-reflectors 303, and through an aperture optic 306 to produce virtual images 23 for a viewer 22. The short part enters the FEC, enters a second FEC 301A to modulate the optical path length, and exits through the aperture optic to be viewed as a virtual image 23 by the viewer. Note here that the virtual image from the short portion is different-specifically, shifted laterally-compared to the virtual image generated by the long portion.

FIG. 3F shows an embodiment in which a display system comprises a display 1 that is a folded display of the C-shape variety. C-shape means that there are three substantially flat portions connected smoothly by bent portions, and the flat portions are approximately the same size. Light from the vertical portion passes into the FEC, through a plurality of first and second semi-reflectors 304, 304, and through the aperture optic 306 to a viewer. The top and bottom portions each enter the FEC 301, are reflected by first semi-reflectors 303, reflected by second semi-reflectors, transmitted by the first semi-reflectors 303 and transmitted to a viewer through the aperture optic. In this embodiment, the first semi-reflectors are polarization-dependent and may be PBSs or reflective polarizers. The second semi-reflectors 304 are polarization changing and may comprise a reflective polarizer and a QWP.

FIGS. 3G and 3H depicts an embodiment in which some of the elements of the display system are curved and which has an electronically controlled of electro-optic element. A display 1 of the C-shape variety emits light into an FEC 301. The top and bottom portions each are reflected by a curved semi-reflector 303, and are transmitted to the outside world through a second semi-reflector 304 and an aperture optic 306. The resulting virtual images 23 have curved focal planes. The central portion of the display 1 emits light into the FEC 301 through a secondary element 305 whose state is controlled by an electronic signal from a circuit block 307. In the first state, as shown in FIG. 3G, the light passes straight through the secondary element 305, the second semi-reflector 304, and the aperture optic 306. In the second state, as shown in FIG. 3H, the light transmitted through the secondary element 305, reflected by the second semi-reflector 304, which is polarization-changing, reflected by the secondary element 305, and finally passed through the second semi-reflector 304 and the aperture optics 306 to form a virtual image 23 at a different depth than in FIG. 3G.

FIG. 3I shows a display 1, which is a folded display of the C-shape variety, sending light from its top and bottom portions into an FEC 301. Light from the top passes through a first semi-reflector 303, is reflected by a second semi-reflector 304, is reflected by the first semi-reflector and exits the cavity. Light from the bottom is transmitted by the second semi-reflector 304 and reflected by the first semi-reflector 303. Both sets of light enter a second FEC 1B that further modulates the depth of the virtual image 23. The light exits the system through an aperture optic 306. In this embodiment, the second FEC may be electronically controlled to dynamically vary the monocular depths of the virtual image.

FIG. 3J shows a display system comprising a display 1, which is a folded display of the L-shape variety. Light from the side portion enters the FEC 301 through a pre-cavity optic 302 and is transmitted by a first semi-reflector 303, through an aperture optic. Light from the top of the display 1 enters the FEC 301, is transmitted through the first semi-reflector 303, is reflected by the second semi-reflector 304 and changed in its polarization state, reflected by the first semi-reflector 303 and transmitted through the aperture optic. The light forms virtual images. In some embodiments, the virtual image is a multifocal virtual image. In some embodiments, the second semi-reflector is curved to produced a curved virtual image. In some embodiments, the first semi-reflector 303 is polarization dependent, such as a PBS or reflective polarizer. In some embodiments, the second semi-reflector 304 is polarization changing, and comprises a QM from FIG. 1.

FIG. 3K shows a display system comprising a display 1, which may be a folded display. In some embodiments, the folded display is of the U-shape variety, meaning that there are three flat portions, and one of those portions is substantially smaller than the others. In some embodiments, the small portion is so small as to be negligible, i.e., the two bent portions merge into one. The light from each side of the display 1 enters a field-evolving cavity 301, which comprises a plurality of first semi-reflectors 303 and second semi-reflectors 304 to guide the light through the cavity. In some embodiments, the long portions of the display are segmented and show multiple display contents, the light from each of the display contents traveling a different optical path, such that the virtual image is a multifocal image.

FIG. 3L shows an embodiment in which the display 1 has a multifunctional purpose. The display 1 is of the S-shape variety, meaning that there are 3 substantially flat regions and the interconnecting bent portions are bent in opposite directions. Light from some of the display enters a field-evolving cavity 301. In some embodiments, the light first travels through a pre-cavity optic 302. The light that exits the FEC 301 forms a virtual image 23. The last portion of the display 1 emits light that does not enter the cavity but is viewable directly, i.e., it is an exposed part. In some embodiments, the display 1 is a touch-sensitive display, such that the viewer can interact with it by touching the exposed part.

FIG. 3M shows a display 1 which is a U-shaped display. The bottom and top portions emit light into a field-evolving cavity 301, optically first passing the light through a pre-cavity optic 302. The FEC 301 may be of any variety of semi-reflectors shown in the previous embodiments. Similarly, FIG. 3N shows an embodiment in which a display 1 is a U-shaped display that emits light into a first field-evolving cavity 301A, which then emits light into a second field-evolving cavity. Light may further couple into a third, fourth, or fifth FEC. The light exits through the last FEC through an aperture optic 306.

FIG. 3O shows an embodiment of a display system that starts with a display 1, which may be a U-shaped type. In this embodiment, the display is called an inverted U-shape because the upper and lower portions emit light away from each other. Each portion emits light into a respective field-evolving cavity, which comprises first and second semi-reflectors 303, 304 to guide the light from the display 1 along various optical paths. The light exits the cavities and enters a relay 309. The relay serves to redirect the light into the appropriate direction. In some embodiments, light first passes through a first relay semi-reflector 309A and be reflected by a second relay semi-reflector 309B to the outside world. Some light first passes through the second relay semi-reflector 309B, is reflected and changes its polarization from the first relay semi-reflector 309A (which may comprise a QBQ, a wave plate and a beam splitter, and the like), and then be reflected by the second relay semi-reflector 309B (which may be polarization dependent, such as a PBS or reflective polarizer) to the outside world.

FIG. 3P shows an embodiment in which the display 1 is a folded display of the sawtooth-shape type. The sawtooth-shape is indicated by having the multiple flat portions of the display form a periodic pattern. In this embodiment, light from a subset of flat portions emits light into a first FEC 301A to produce a first virtual image 23A, and light from a second subset of flat portions emits light into a second FEC 301B to produce a second virtual image 23B. In some embodiments, the sawtooth phase or frequency through a circuit block 307 that applies an acoustic modulating wave to display.

The embodiment in FIG. 3Q uses light from both the flat portions of a display 1 and also its bent portion 1B. Some of the flat portion emit light into the FEC 301, through first specular reflectors 303 and a second specular reflector 304. Some of the flat portion emits light into the FEC 301, through a first specular reflector 303, after which the light is reflected by the second specular reflector 304, reflected by the other first specular reflector 303, and then passes through the second specular reflector 304 and the aperture optic 306.

The bent portion emits light through a direction-changing element 310 after in enters the FEC 301. In some embodiments the directional-changing element is a prism, a lens or lenslet array, a directional film, and the like. The flat portions produce a virtual image 23, and the bent portion produces a virtual image 23B. In some embodiments, the light from the bent portion travels multiple round trips in the FEC. An example of the virtual image 23B produced by the bent portion 1B may be a display bar to show various icons to the viewer.

FIG. 3R shows an embodiment in which the display 1 is bent to follow a surface of a vehicular part 311, which may be a dashboard, seat back, side door, and the like. The light enters the FEC 301 and exits through the aperture optic 306 to form a virtual image 23.

In some embodiments, components besides the display are bent. For example, in FIG. 3S, a display 1, which is a folded display, emits light through pre-cavity optics 302. The light then enters an FEC that comprises a monolithic semi-reflective element 312 that is bent around supports 313. Some portions of the monolithic semi-reflective element serve as a first semi-reflector, and other portions serve as a second semi-reflector, which passes the light through an aperture optic 306 into the external environment.

FIG. 3T shows a similar embodiment in which the display 1 is a folded display, and the light from it enters the field-evolving cavity through a folded semi-reflector 312. In this embodiment, the folded semi-reflector 312 has two flat portions that replace two individual semi-reflectors. The folded semi-reflector may be coated onto the display, or it may be a separate component. The light exits the FEC through the aperture optic 306.

The bent portions of the semi-reflectors in FIGS. 3S and 3T have arbitrary radius of curvature. In some embodiments, the radius is 10 cm, 9 cm, 8 cm, 7 cm, 6 cm, 5 cm, 4 cm, 3 cm, 2cm, 1 cm, 0.5 cm, or 0.1 cm.

FIG. 3U shows an example of a display system wherein the display 1 is a folded display that follows the contours of a vehicular surface 310. A substantially flat portion of the display emits light into a field-evolving cavity 301 and is reflected by a first semi-reflector 303. The other part of the folded display has more bends and would generally produce a distorted image after sending light into the FEC 301. In this embodiment, a compensating element 313 is inserted into the beam path to correct those distortions and contribute to a clear virtual image 23. The compensating element may be a phased array, a spatial light modulator, a digital micromirror, a prism, a freeform lens, a lenslet array, or a metasurface.

FIG. 3V shows an example of a display system where the display 1 is a folded display that is twisted, such that the subset of flat portions of the display emit light in non-collinear directions. A first portion of light travels through a first FEC 301A to produce a first virtual image 23B. A second portion of light travels through a second FEC 301B to produce a second virtual image 23B.

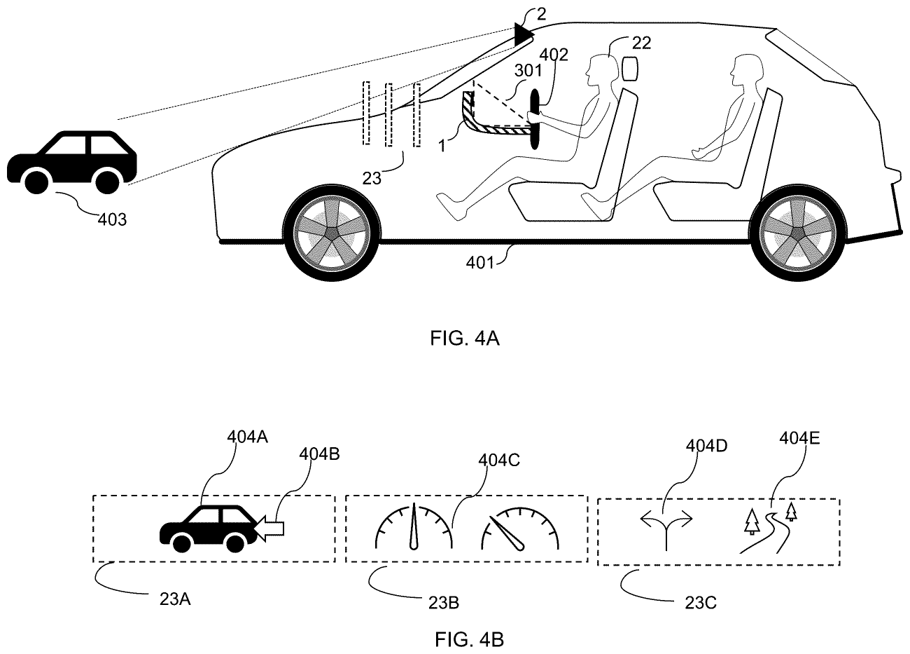

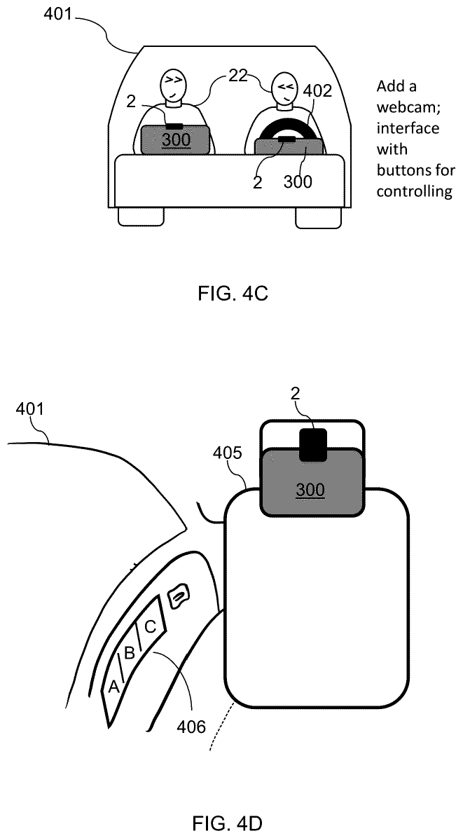

FIGS. 4A through 4D depict embodiments that integrate the display systems described here into a vehicle. FIG. 4A shows the display system, which comprises a display 1 and a FEC 301 as an instrument cluster behind the steering wheel 402 of a vehicle 401. In some embodiments, the viewer 22 is a driver of the vehicle. In some embodiments, a camera 2 captures information about the external environment, such as the environment outside the vehicle.

FIG. 4B shows a set of virtual images that said driver observers. In some embodiments a first virtual image 23A shows information from the camera 2 of FIG. 4A as well as annotations 404B overlaid on. A second virtual image 23B shows the vehicle's instrument cluster 404C, which may include information about the vehicle's status, such as its speed, acceleration, battery level, fuel level, engine temperature, and the like. A third virtual image 23C shows a navigation system which includes direction information 404D and a local map 404E.

FIG. 4C shows an embodiment in which multiple display systems are integrated into a vehicle 401. In some embodiments, on of the viewers 22 is a driver behind a steering wheel 402 and has access to a display system 300 and a camera 2. The camera 2 may collect information about the driver's state, such as fatigue or eye fixation. A passenger may also be a viewer 22 to his own display system 300 which may include a camera 2 that can serve as a teleconferencing system.

FIG. 4D shows an embodiment in which the display system 300 and a camera 2 are integrated into a seatback 405 for rear-passenger viewing. Integrated into a part of a vehicle, such as the car door 401 is an interactive interface 406 to control the display system. In some embodiments, it is integrated into a center console for front passenger and driver, or into the steering wheel or steering column for driver use.

The interactive interface 406 may consist of a remote, buttons, touch screen, or gesture sensors. The interface allows a viewer to modify the display content. In some embodiments involving a multifocal virtual image, the interactive interface controls which display content shows on which focal plane.

In some instances, a module may be identified as a hardware module or a software module. A hardware module includes or shares the hardware for implementing the capability of the module. A hardware module may include software, that is, it may include a software module. A software module comprises information that may be stored, for example, on a non-transitory computer-readable storage medium. In some embodiments, the information may comprise instructions executable by one or more processors. In some embodiments, the information may be used at least in part to configure hardware such as an FPGA. In some embodiments, an algorithm may be recorded as a software module. The capability may be implemented, for example, by reading the software module from a storage medium and executing it with one or more processors, or by reading the software module from a storage medium and using the information to configure hardware.

In this document, the terms “machine readable medium,” “computer readable medium,” and similar terms are used to refer to non-transitory mediums, volatile or non-volatile, that store data and/or instructions that cause a machine to operate in a specific fashion. Common forms of machine-readable media include, for example, a hard disk, solid state drive, magnetic tape, or any other magnetic data storage medium, an optical disc or any other optical data storage medium, any physical medium with patterns of holes, a RAM, a PROM, EPROM, a FLASH-EPROM, NVRAM, any other memory chip or cartridge, and networked versions of the same.

These and other various forms of computer readable media may be involved in carrying one or more sequences of one or more instructions to a processing device for execution. Such instructions embodied on the medium, are referred to as “instructions” or “code.” Instructions may be grouped in the form of computer programs or other groupings. When executed, such instructions may enable a processing device to perform features or functions of the present application as discussed herein.

In this document, a “processing device” may be implemented as a single processor that performs processing operations or a combination of specialized and/or general-purpose processors that perform processing operations. A processing device may include a CPU, GPU, APU, DSP, FPGA, ASIC, SOC, and/or other processing circuitry.

The various embodiments set forth herein are described in terms of exemplary block diagrams, flow charts and other illustrations. As will become apparent to one of ordinary skills in the art after reading this document, the illustrated embodiments and their various alternatives can be implemented without confinement to the illustrated examples. For example, block diagrams and their accompanying description should not be constructed as mandating a particular architecture or configuration.

Each of the processes, methods, and algorithms described in the preceding sections may be embodied in, and fully or partially automated by, code components executed by one or more computer systems or computer processors comprising computer hardware. The processes and algorithms may be implemented partially or wholly in application-specific circuitry. The various features and processes described above may be used independently of one another or may be combined in several ways. Different combinations and sub-combinations are intended to fall within the scope of this disclosure, and certain method or process blocks may be omitted in some implementations. Additionally, unless the context dictates otherwise, the methods and processes described herein are also not limited to any particular sequence, and the blocks or states relating thereto can be performed in other sequences that are appropriate, or may be performed in parallel, or in some other manner. Blocks or states may be added to or removed from the disclosed example embodiments. The performance of certain operations or processes may be distributed among computer systems or computers processors, not only residing within a single machine, but deployed across a number of computational resources.

As used herein, the term “or” may be constructed in either an inclusive or exclusive sense. Moreover, the description of resources, operations, or structures in the singular shall not be read to exclude the plural. Conditional language, such as, among others, “can,” “could,” “might,” or “may,” unless specifically stated otherwise, or otherwise understood within the context as used, is generally intended to convey that certain embodiments include, while other embodiments do not include, certain features, elements and/or steps.

Terms and phrases used in this document, and variations thereof, unless otherwise expressly stated, should be constructed as open ended as opposed to limiting. Adjectives such as “conventional,” “traditional,” “normal,” “standard,” “known,” and terms of similar meaning should not be constructed as limiting the item described to a given time period or to an item available as of a given time, but instead should be read to encompass conventional, traditional, normal, or standard technologies that may be available or known now or at any time in the future. The presence of broadening words and phrases such as “one or more,” “at least,” “but not limited to” or other like phrases in some instances shall not be read to mean that the narrower case is intended or required in instances where such broadening phrases may be absent.

What is claimed:

1. A system comprising:
a folded display having a plurality of flat portions continuously connected by at least a bent portion, the plurality of flat portions capable of emitting light;
a plurality of first polarization-changing semi-reflectors disposed to receive the light emitted from the plurality of flat portions;
a second polarization-changing semi-reflector to reflect a portion of the light received from the first polarization-changing semi-reflectors; and
an aperture optic to direct the light out of the system, wherein
the light emitted from the plurality of flat portions is guided along a plurality of optical paths within the system by the plurality of first polarization-changing semi-reflectors, the second polarization-changing semi-reflector, and the aperture optic, and
the light forms a virtual image with respect to a headbox outside the system.

2. The system of claim 1, wherein the virtual image is a multifocal image.

3. The system of claim 1, wherein the virtual image has a monocular depth that is larger than a distance between the folded display and the headbox.

4. The system of claim 1, wherein the aperture optic comprises an absorptive polarizer, and an antireflection layer.

5. The system of claim 1, wherein the plurality of first polarization changing semi-reflectors comprises a first wave plate and a first beam splitter, and the second polarization-changing semi-reflector comprises a second wave plate and a second beam splitter.

6. The system of claim 1, wherein the system is integrated as an instrument cluster of a vehicle.

7. The system of claim 1, wherein a shape of the folded display is selected from the group consisting of a C-shape, a U-shape, an L-shape, a sawtooth-shape, and combinations thereof.

8. The system of claim 1, wherein at least one polarization-changing semi-reflector among the first plurality of polarization-changing semi-reflectors and the second polarization-changing semi-reflector comprises an electro-optic (EO) material.

9. The system of claim 1, wherein at least one of the plurality of optical paths is partially folded onto itself.

10. The system of claim 1, wherein a lateral size of the virtual image is larger than a lateral size of the aperture optic.

11. The system of claim 1, wherein the headbox spans a lateral dimension of at least 15 cm.

12. A system comprising:
a folded display panel having a plurality of substantially flat portions, the plurality of substantially flat portions capable of emitting light rays; and
a field-evolving cavity having
a plurality of specular reflectors to receive the light rays and to guide the light rays along a plurality of optical paths within the field-evolving cavity; and
an aperture optic to transmit the light rays out of the field-evolving cavity to form a virtual image.

13. The system of claim 12, wherein the virtual image is a multifocal virtual image.

14. The system of claim 12, wherein the field evolving cavity further comprises an electro-optic (EO) plate disposed along at least one of the optical paths.

15. The system of claim 12, wherein the plurality of specular reflectors comprise a wave plate and a beam splitter.

16. The system of claim 12, where adjacent ones of the plurality of substantially flat portions of the folded display are oriented at a right angle relative each other.

17. The system of claim 12, wherein the system is integrated into a vehicle as an instrument cluster or navigation system.

18. A system comprising:
a folded display having a plurality of flat portions continuously connected by one or more bent portions, the plurality of flat portions capable of emitting light;
a field-evolving cavity to direct a first portion of the light from the folded display to produce a virtual image, the field-evolving cavity having
a plurality of polarization-dependent specular reflectors; and
an aperture optic,
wherein at least one of the plurality of flat portions of the folded display is touch sensitive and emits a second portion of the light that traverses away from the field-evolving cavity.

19. The system of claim 18, wherein the plurality of polarization-dependent specular reflectors comprises a quarter-wave plate and a beam splitter.

20. The system of claim 18, wherein the aperture optic comprises a reflective polarizer, an absorptive polarizer, and an antireflection layer.

21. The system of claim 18, wherein the system is integrated into a vehicle.
